(19) United States
(12) Patent Application Publication
(10) Pub. No.: US 2025/0147374 A1
(43) Pub. Date: May 8, 2025

(54) CONTINUOUS PHOTOLITHOGRAPHIC FABRICATION PROCESS FOR PRODUCING SEAMLESS MICROSTRUCTURES USED IN ELECTRO-OPTIC DISPLAYS AND LIGHT MODULATING FILMS

(71) Applicant: E INK CORPORATION, Billerica, MA (US)

(72) Inventors: Yu XIA, Acton, MA (US); Brian DUNN, Medford, MA (US); Stephen J. TELFER, Arlington, MA (US); Yih-Ming KANG, Fremont, CA (US); Hjalmar Edzer Ayco HUITEMA, Lexington, MA (US)

(21) Appl. No.: 18/917,211

(22) Filed: Oct. 16, 2024

Related U.S. Application Data
(60) Provisional application No. 63/547,747, filed on Nov. 8, 2023.

(51) Int. Cl. G02F 1/167; G02F 1/1675; G02F 1/1681

(52) U.S. Cl. CPC G02F 1/167; G02F 1/1681; G02F 2001/1678

(57) ABSTRACT

A roll-to-roll method of fabricating seamless microstructures is provided, including the steps of: (a) continuously forming a laminated structure comprising a photomask film superimposed on a substrate with a layer of photo-sensitive material therebetween, the photomask film including a pattern of light-transmissive regions and light-blocking regions; (b) illuminating the photomask film of laminated structure formed in step (a) such that light passes through the light-transmissive regions of the photomask film to cure portions of the photo-sensitive material exposed by the light-transmissive regions, while leaving the remaining portions of the photo-sensitive material covered by the light-blocking regions uncured; (c) delaminating the photomask film from the photo-sensitive material selectively cured in step (b); and (d) removing the uncured portions of the photo-sensitive material to form a layer of microstructures on the substrate from the cured portions of the photo-sensitive material.

### CROSS REFERENCE TO RELATED APPLICATIONS

This application claims priority from U.S. Provisional Patent Application No. 63/547,747 filed on Nov. 8, 2023 entitled CONTINUOUS PHOTOLITHOGRAPHIC FABRICATION PROCESS FOR PRODUCING SEAMLESS MICROSTRUCTURES USED IN ELECTRO-OPTIC DISPLAYS AND LIGHT MODULATING FILMS, which is hereby incorporated by reference in its entirety.

### BACKGROUND

The present application generally relates to electrophoretic and other electro-optic displays and light modulating films and, more particularly, to a continuous photolithographic fabrication process for producing seamless microstructures used in such displays and films.

Electrophoretic light modulating films modulate the amount of light or other electro-magnetic radiation passing through an electrophoretic medium. In some instances, the light will pass completely through the film (i.e., from top to bottom). In other instances, the light may pass through the electrophoretic medium, reflect/scatter off a surface, and return through the medium a second time (i.e., from top to bottom surfaces and back to top.) In other instances, the light will be absorbed by pigment particles present at the viewing surface. In other instances, selective absorption of the light by pigment particles will result in a rendered image, e.g., text or a picture. Such films can be incorporated into displays, signs, variable transmission windows, mirrors, displays, and similar devices. Typically the films have an “open” state, in which one or more sets of pigment particles are isolated to the side or in wells, etc., so that most of the incident light can pass through the medium, and a “closed” state, in which one or more sets of pigment particles are distributed through the medium to absorb some or all of the incident light.

For example, U.S. Pat. No. 10,067,398 discloses an electrophoretic light attenuator comprising a cell including a first substrate, a second substrate spaced apart from the first substrate, a layer arranged between the substrates containing an electrophoretic ink, and a monolayer of closely packed microstructure protrusions projecting into the electrophoretic ink and arranged adjacent a surface of the second substrate. The protrusions have surfaces defining a plurality of depressions between adjacent protrusions. The electrophoretic medium layer (ink layer) includes charged particles of at least one type, the particles being responsive to an electric field applied to the cell to move between a first extreme light state, in which the particles are maximally spread within the cell so as to lie in the path of light through the cell and thus strongly attenuate light transmitted from one substrate to the opposite substrate, and a second extreme light state, in which the particles are maximally concentrated within the depressions so as to let light be transmitted. The total area corresponding to the concentrated particles in the depressions is a fraction of the total face area.

Devices of this type rely at least in part on the shape of their non-planar polymer structure to concentrate absorbing charged particles (e.g., black particles) in an electrophoretic ink in a transparent light state thereby forming (or exposing) light apertures (i.e., transmitting areas) and light obstructions (i.e., strongly absorbing areas). The present application additionally relates to more traditional electrophoretic displays, such as described in U.S. Pat. Nos. 9,921,451 and 9,812,073, which modulate the light reflected at the viewing surface with the presence of charged pigment particles.

Prior art solutions that have a polymer structure in the fluid or gel layer include U.S. Pat. No. 8,508,695 to Vlyte Innovations Ltd., which discloses dispersing fluid droplets (1 to 5 microns in diameter) in a continuous polymer matrix that is cured in place to both substrates, to contain liquid crystals. Additionally, U.S. Pat. No. 10,809,590 to E Ink Corporation discloses microencapsulating fluid droplets and deforming them to form a monolayer of close packed polymer shells in a polymer matrix on one substrate and subsequently applying an adhesive layer to bond the capsule layer to a substrate. Also, European Patent Application Publication EP1264210 to E Ink California discloses embossing a microcell structure (comprising a plurality of cavities or cups) on one substrate, filling the cups with fluid having polymerizable components and polymerizing the components to form a scaling layer on the fluid/cup surface, then applying an adhesive layer to bond to the second substrate. Additionally, EP2976676 to Vlyte Innovations Ltd. discloses forming a wall structure on one substrate, coating the tops of walls with adhesive, filling the cavities defined by the walls with fluid, and polymerizing the adhesive to bond the tops of walls to the opposing substrate. EP3281055 describes a flexible device including solid polymer microstructures embedded in its viewing area and the microstructures are on both substrates. The microstructures join (i.e., fasten) the substrates of the device to each other by engaging with each other over a length orthogonal to the substrates. The joined microstructures incorporate a wall structure that divides a device's fluid layer into a monolayer of discrete volumes contained within corresponding cavities. This provides the device with significant structural strength. In the method described, mating microstructures (i.e., male and female parts) are formed on each substrate, then precisely aligned with each other and joined in a press fit that also seals the fluid layer in the cavities.

Particle-based electrophoretic displays, in which a plurality of charged particles move through a suspending fluid under the influence of an electric field, have been the subject of intense research and development for a number of years. Such displays can have attributes of good brightness and contrast, wide viewing angles, state bistability, and low power consumption when compared with liquid crystal displays. The terms “bistable” and “bistability” are used herein in their conventional meaning in the art to refer to displays comprising display elements having first and second display states differing in at least one optical property, and such that after any given element has been driven, by means of an addressing pulse of finite duration, to assume either its first or second display state, after the addressing pulse has terminated, that state will persist for at least several times, e.g., at least four times, the minimum duration of the addressing pulse required to change the state of the display element. It is shown in U.S. Pat. No. 7,170,670 that some particle-based electrophoretic displays capable of gray scale are stable not only in their extreme black and white states but also in their intermediate gray states, and the same is true of some other types of electro-optic displays. This type of display is properly called “multi-stable” rather than bistable, although for convenience the term “bistable” may be used herein to cover both bistable and multi-stable displays.

As noted above, electrophoretic media require the presence of a suspending fluid. In most prior art electrophoretic media, this suspending fluid is a liquid, but electrophoretic media can be produced using gaseous suspending fluids; sec, e.g., Kitamura, T., et al., “Electrical toner movement for electronic paper-like display”, IDW Japan, 2001, Paper HCS1-1, and Yamaguchi, Y, et al., “Toner display using insulative particles charged triboelectrically”, IDW Japan, 2001, Paper AMD4-4). See also European Patent Applications 1,429,178; 1,462,847; and 1,482,354; and International Applications WO 2004/090626; WO 2004/079442; WO 2004/077140; WO 2004/059379; WO 2004/055586; WO 2004/008239; WO 2004/006006; WO 2004/001498; WO 03/091799; and WO 03/088495. Such gas-based electrophoretic media appear to be susceptible to the same types of problems due to particle settling as liquid-based electrophoretic media, when the media are used in an orientation that permits such settling, e.g., in a sign where the medium is disposed in a vertical plane. Indeed, particle settling appears to be a more serious problem in gas-based electrophoretic media than in liquid-based ones since the lower viscosity of gaseous suspending fluids as compared with liquid ones allows more rapid settling of the electrophoretic particles.

Numerous patents and applications assigned to or in the names of the Massachusetts Institute of Technology (MIT) and E Ink Corporation, E Ink California, LLC, and related companies describe various technologies used in encapsulated and microcell electrophoretic and other electro-optic media. Encapsulated electrophoretic media comprise numerous small capsules, each of which itself comprises an internal phase containing electrophoretically-mobile particles in a fluid medium, and a capsule wall surrounding the internal phase. Typically, the capsules are themselves held within a polymeric binder to form a coherent layer positioned between two electrodes. In a microcell electrophoretic display, the charged particles and the fluid are not encapsulated within microcapsules but instead are retained within a plurality of cavities formed within a carrier medium, typically a polymeric film. The technologies described in these patents and applications include:
(a) Electrophoretic particles, fluids and fluid additives; see, e.g., U.S. Pat. Nos. 7,002,728 and 7,679,814;
(b) Capsules, binders and encapsulation processes; see, e.g., U.S. Pat. Nos. 6,922,276 and 7,411,719;
(c) Microcell structures, wall materials, and methods of forming microcells; see for example U.S. Pat. Nos. 7,072,095 and 9,279,906;
(d) Methods for filling and sealing microcells; see, e.g., U.S. Pat. Nos. 7,144,942 and 7,715,088;
(e) Films and sub-assemblies containing electro-optic materials; see, e.g., U.S. Pat. Nos. 6,982,178 and 7,839,564;
(f) Backplanes, adhesive layers and other auxiliary layers and methods used in displays; see, e.g., U.S. Pat. Nos. 7,116,318 and 7,535,624;
(g) Color formation and color adjustment; see, e.g., U.S. Pat. Nos. 7,075,502 and 7,839,564;
(h) Methods for driving displays; see, e.g., U.S. Pat. Nos. 7,012,600 and 7,453,445;
(i) Applications of displays; see, e.g., U.S. Pat. Nos. 7,312,784 and 8,009,348; and
(j) Non-electrophoretic displays, as described in U.S. Pat. No. 6,241,921 and U.S. Patent Applications Publication No. 2015/0277160; and applications of encapsulation and microcell technology other than displays; see, e.g., U.S. Patent Application Publications Nos. 2015/0005720 and 2016/0012710.

Many of the aforementioned patents and applications recognize that the walls surrounding the discrete microcapsules in an encapsulated electrophoretic medium could be replaced by a continuous phase, thus producing a so-called polymer-dispersed electrophoretic display, in which the electrophoretic medium comprises a plurality of discrete droplets of an electrophoretic fluid and a continuous phase of a polymeric material, and that the discrete droplets of electrophoretic fluid within such a polymer-dispersed electrophoretic display may be regarded as capsules or microcapsules even though no discrete capsule membrane is associated with each individual droplet; see, e.g., the aforementioned U.S. Patent Application Publication No. 2002/0131147. Accordingly, for purposes of the present application, such polymer-dispersed electrophoretic media are regarded as sub-species of encapsulated electrophoretic media.

Electrophoretic media are often opaque (since, e.g., in many electrophoretic media, the particles substantially block transmission of visible light through the display) and operate in either a light-absorptive or a light-reflective mode. However, electrophoretic devices can also be made to operate in a so-called “shutter mode,” in which one display state is substantially opaque and one is substantially light-transmissive. See, e.g., the aforementioned U.S. Pat. Nos. 6,130,774 and 6,172,798, and U.S. Pat. Nos. 5,872,552; 6,144,361; 6,271,823; 6,225,971; and 6,184,856. Dielectrophoretic displays, which are similar to electrophoretic displays but rely upon variations in electric field strength, can operate in a similar mode; see U.S. Pat. No. 4,418,346. Other types of electro-optic displays may also be capable of operating in shutter mode. In particular, when this “shutter mode” electrophoretic device is constructed on a transparent substrate, it is possible to regulate transmission of light through the device.

An encapsulated or microcell electrophoretic display typically does not suffer from the clustering and settling failure mode of traditional electrophoretic devices and provides further advantages, such as the ability to print or coat the display on a wide variety of flexible and rigid substrates. (Use of the word “printing” is intended to include all forms of printing and coating, including, but without limitation: pre-metered coatings such as patch die coating, slot or extrusion coating, slide or cascade coating, curtain coating; roll coating such as knife over roll coating, forward and reverse roll coating; gravure coating; dip coating; spray coating; meniscus coating; spin coating; brush coating; air knife coating; silk screen printing processes; electrostatic printing processes; thermal printing processes; ink jet printing processes; electrophoretic deposition; and other similar techniques.) Thus, the resulting display can be flexible. Further, because the display medium can be printed (using a variety of methods), the display itself can be made inexpensively.

One potentially important market for electrophoretic media is windows with variable light transmission. As the energy performance of buildings becomes increasingly important, electrophoretic media could be used as coatings on windows to enable the proportion of incident radiation transmitted through the windows to be electronically controlled by varying the optical state of the electrophoretic media. Effective implementation of such “variable-transmissivity” (“VT”) technology in buildings is expected to provide (1) reduction of unwanted heating effects during hot weather, thus reducing the amount of energy needed for cooling, the size of air conditioning plants, and peak electricity demand; (2) increased use of natural daylight, thus reducing energy used for lighting and peak electricity demand; and (3) increased occupant comfort by increasing both thermal and visual comfort. Even greater benefits would be expected to accrue in an automobile or other vehicle, where the ratio of glazed surface to enclosed volume is significantly larger than in a typical building. Specifically, effective implementation of VT technology in automobiles is expected to provide not only the aforementioned benefits but also (1) increased motoring safety, (2) reduced glare, (3) enhanced mirror performance (by using an electro-optic coating on the mirror), and (4) increased ability to use heads-up displays. Other potential applications of VT technology include privacy glass and glare-guards in electronic devices.

Many switchable electrophoretic light modulator and display applications require coverage of large areas. For example, the light modulator may be used in an office building window that is several meters by several meters in area, or the electrophoretic display may be a wide format sign having a diagonal measurement of greater than 1 meter. One factor limiting manufacturing of such large modulators and displays is the difficulty of manufacturing seamless patterns of large-area polymer structures used in the devices.

Polymer structures containing high resolution 3D microstructures can be fabricated by photolithography using a photomask or by an embossing process with a negative-structure shim. Photolithography has high resolution, but is typically a slow sheet-to-sheet process. Roll-to-roll embossing processes facilitate continuous high-throughput production, but the roll width is limited by the size of the shim and it is difficult to make seamless patterns due to the connection region where the shim is mounted on a drum. Lithography processes using cylindrical masks also have difficulty achieving seamless patterns. A need exists for a process for manufacturing a seamless pattern of microstructures on a roll with width greater than 1 m and preferably at a process speed greater than 10 ft/min. A need also exists for a process for manufacturing a polymer structure having multiple layers of microstructures, potentially comprising different materials.

SUMMARY

A roll-to-roll method of fabricating seamless microstructures is provided, comprising the steps of: (a) continuously forming a laminated structure comprising a photomask film superimposed on a substrate with a layer of photo-sensitive material therebetween, the photomask film including a pattern of light-transmissive regions and light-blocking regions; (b) illuminating the photomask film of laminated structure formed in step (a) such that light passes through the light-transmissive regions of the photomask film to cure portions of the photo-sensitive material exposed by the light-transmissive regions, while leaving the remaining portions of the photo-sensitive material covered by the light-blocking regions uncured; (c) delaminating the photomask film from the photo-sensitive material selectively cured in step (b); and (d) removing the uncured portions of the photo-sensitive material to form a layer of microstructures on the substrate from the cured portions of the photo-sensitive material.

In accordance with one or more embodiments, step (a) of the method comprises advancing the photomask film, the substrate, and the layer of photo-sensitive material between a pair of pinch rollers to form the laminated structure.

In accordance with one or more embodiments, the light comprises ultra-violet (UV) light.

In accordance with one or more embodiments, the photo-sensitive material comprises a negative type UV-sensitive material.

In accordance with one or more embodiments, the microstructures comprise cross-linked UV light cured structures.

In accordance with one or more embodiments, the method further comprises reusing the photomask film delaminated in step (c) of the method in a subsequent microstructure fabrication process.

In accordance with one or more embodiments, steps (a) and (b) of the method are performed in a multi-coating-head production line.

In accordance with one or more embodiments, step (b) of the method is performed while the laminated structure is in transit.

In accordance with one or more embodiments, the layer of photo-sensitive material is coated on the substrate prior to step (a), preferably using a rod, bar, blade, or slot-die coating process.

In accordance with one or more embodiments, the substrate laminated in step (a) includes a preexisting set of microstructures formed thereon.

In accordance with one or more embodiments, the preexisting set of microstructures were formed by a prior embossing process performed on the substrate.

In accordance with one or more embodiments, the preexisting set of microstructures were formed by a prior microstructure fabrication process involving the substrate comprising steps (a), (b), (c), and (d).

In accordance with one or more embodiments, the method further comprises withdrawing the photomask film and the substrate from respective rolls prior to step (a).

In accordance with one or more embodiments, the width of each roll is greater than one meter.

In accordance with one or more embodiments, the microstructures comprise features having an X/Y dimension resolution of 200 μm to 2000 μm and a Z dimension resolution of 1 μm to 500 μm.

In accordance with one or more embodiments, the substrate having the layer of microstructures formed thereon has a width greater than one meter.

In accordance with one or more embodiments, the substrate having the layer of microstructures formed thereon has a length greater than 1 m.

In accordance with one or more embodiments, the microstructure fabrication process has a speed greater than 3 meters/minute.

In accordance with one or more embodiments, step (d) of the method comprises introducing the photo-sensitive material and substrate in a solvent bath for dissolving the uncured portions of the photo-sensitive material to form the layer of microstructures on the substrate.

In accordance with one or more embodiments, the microstructure fabrication method produces a seamless roll of the substrate with the layer of microstructures thereon.

In accordance with one or more embodiments, the photomask film comprises a photomask pattern printed on a release liner.

In accordance with one or more embodiments, the photomask pattern faces and is adjacent to the photo-sensitive material.

In accordance with one or more embodiments, the release liner faces and is adjacent to the photo-sensitive material.

In accordance with one or more embodiments, the layer of microstructures on the substrate is used in constructing an electrophoretic device.

In accordance with one or more embodiments, the photomask film includes grey scale features to alter the intensity of the light incident on the photo-sensitive material to vary the heights of the microstructures.

These and other aspects of the present invention will be apparent in view of the following description.

### BRIEF DESCRIPTION OF THE DRAWINGS

Embodiments of the invention will now be described by way of example with reference to the accompanying drawings, in which:

FIGS. 1A-1D are simplified cross-sectional diagrams illustrating an exemplary continuous photolithography fabrication process for producing microstructures used in electrophoretic and other electro-optic devices in accordance with one or more embodiments.

FIG. 2 is a simplified cross-sectional diagram illustrating an exemplary continuous photolithography fabrication process in which the photomask film is inverted in accordance with one or more embodiments.

FIG. 3 is a simplified cross-sectional diagram illustrating an exemplary continuous photolithography fabrication process for producing multiple layers of microstructures on a substrate in accordance with one or more embodiments.

FIG. 4 is a simplified cross-sectional diagram illustrating an exemplary continuous photolithography fabrication process for producing microstructures on a substrate having photomask elements in accordance with one or more embodiments.

FIG. 5 is a simplified cross-sectional diagram illustrating an exemplary continuous photolithography fabrication process for producing microstructures on a substrate using two photomask films in accordance with one or more embodiments.

FIG. 6 is a plan view of an exemplary thin-film photomask with an emulsion photolithographic pattern in accordance with one or more embodiments.

FIG. 7 is a diagram showing the measured topography of the microstructures formed in accordance with one or more embodiments.

FIG. 8 is a diagram showing the measured topography of another set of microstructures formed in accordance with one or more embodiments.

Like or identical reference numbers are used to indicate common or similar elements.

The drawing depict one or more implementations in accord with the present concepts, by way of example only, not by way of limitations.

### DETAILED DESCRIPTION

Various embodiments disclosed herein relate to a continuous photolithography fabrication process for producing microstructures used in large-area electrophoretic displays and light modulating films. In one or more embodiments, a continuous lithography process is disclosed using a thin film photomask that can have the same length as the substrate on which the microstructures are formed. This process enables seamless, roll-to-roll lithography patterning of microstructures such as microcell walls and non-planar polymer structures used in electrophoretic devices on a roll with width greater than 1 m and preferably at a process speed greater than 10 ft/min. In addition, the process allows for improved control of microstructure thickness, and enables patterning multiple layers of potentially different materials to form more complex microstructures. For example, the process can produce transparent cone and well microstructures overlaid with a black wall for transmittance control in a light modulating film.

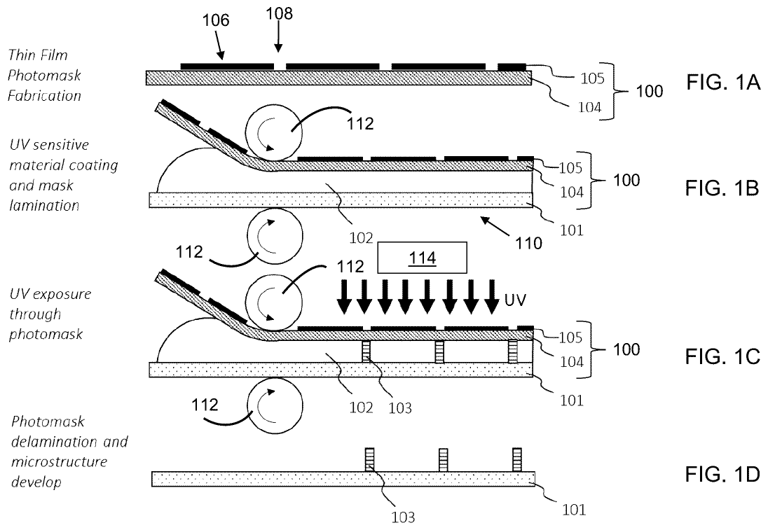

FIGS. 1A-1D are simplified cross-sectional views illustrating an exemplary continuous photolithography fabrication process for producing microstructures used in electrophoretic devices in accordance with one or more embodiments. The process utilizes a thin-film photomask 100 shown in FIG. 1A comprising a printed light-blocking layer 105 on a release liner 104, which can, e.g., be a plastic substrate. The light-blocking layer 105 can be formed by applying print black or reflective materials on the release liner 104 to define a pattern of light-blocking regions 106 and light-transmissive regions 108. Various printing processes can be used for applying print black or reflective materials on the release liner 104 including, but not limited to, screen, lithography, flexography, inkjet, aerosol jet, and gravure printing. Some of the known printing methods comprise continuous roll-to-roll printing of seamless, high-resolution photomasks (see, e.g., U.S. Pat. No. 10,479,905).

As shown in FIG. 1B, a laminated structure 110 is continuously formed comprising the thin-film photomask 100, a photo-sensitive material 102, and a substrate 101. The photo-sensitive material 102 is nip-coated between the thin-film photomask 100 and the substrate 101 as the materials are fed between a pair of pinch rollers 112.

The photo-sensitive material 102 can be positive or negative photoresist, comprising various kinds of photo-sensitive polymers such as polyimide, acrylic resins, or epoxy resins. For example, the photo-sensitive material 102 can be a Diazonaphthoquinone (DNQ)-Novolac resin, a common type of positive photoresist. The photo-sensitive material 102 can also comprise dual-cure, thiol-ene, and other crosslinking chemistry compositions commonly used as negative photoresists. In one or more preferred embodiments, the photo-sensitive material 102 comprises a negative-type ultraviolet (UV) photo-sensitive material.

The substrate 101 can comprise various materials depending on its intended use in the electrophoretic device. For example, the substrate can comprise an Indium Tin Oxide (ITO) coated Polyethylene Terephthalate (PET) film to form a microcell cavity layer in an electrophoretic display device, or the substrate can comprise a polymeric film to form non-planar polymer structures to concentrate absorbing charged particles in a light attenuator. In other examples, the substrate comprises a flexible material such as a clear plastic or glass, which can be coated with a conductive layer (e.g., ITO). Suitable plastics include, e.g., polycarbonate (PC), polycarbonate and copolymer blends, polyethersulfone (PES), cellulose triacetate (TAC), polyamide, p-nitrophenylbutyrate (PNB), a polyetheretherketone (PEEK), a polyethylenenapthalate (PEN), polyetherimide (PEI), polyarylate (PAR), or other similar plastics known in the art. Flexible glass can include materials such as Corning® Willow® Glass, etc.

The laminated structure 110 is then illuminated as it is in transit advancing past a light source 114 (e.g., a UV light source) as shown in FIG. IC. If the photo-sensitive material 102 is a negative-type photo-sensitive material, light from the light source 114 passes through the light-transmissive regions 108 of the photomask film 100 to cure portions of the photo-sensitive material 102 exposed by the light-transmissive regions 108, while leaving the remaining portions of the photo-sensitive material 102 covered by the light-blocking regions 106 uncured.

The photomask film 100 is then delaminated from the selectively cured photo-sensitive material 102. This step can be performed continuously using a releasing roller.

Then, as shown in FIG. ID, the uncured portions of the photo-sensitive material 102 are removed, leaving a desired pattern of UV-cross-linked microstructures 103 on the substrate 101. This development step can be performed, e.g., by soaking the photo-sensitive material 102 in a solvent bath that dissolves uncured portions of the photo-sensitive material 102. This step can be performed continuously while the material is in transit.

If the photo-sensitive material 102 is a positive-type photo-sensitive material, light from the light source 114 makes the exposed portions of the photo-sensitive material 102 more soluble to the solvent, so that the exposed portions can be removed to form the microstructures 103 from the remaining unexposed portions of the photo-sensitive material.

A seamless roll of microstructures 103 (e.g., UV-cross-linked microstructures) shown in FIG. 1D is thereby produced.

The thin-film photomask 100 can be made in generally any desired length. For example, the thin film photomask 100 that can have the same length as the substrate 101 on which the microstructures 103 are formed. In addition, the microstructures 103 can be formed on rolls having a width greater than 1 m. As a result, large-area seamless patterns of microstructures 103 can be produced for large-area electrophoretic light modulators and displays.

In one or more embodiments, the process is a roll-to-roll process having a process speed greater than 10 ft/min.

In one or more embodiments, surface energy modification of the substrate 101 and release liner 104 is performed reduce residue from removal of the photomask 100 and to provide robust microstructures 103 with good adhesion to the substrate 101.

In one or more embodiments, the thin-film photomask 100 can be reused multiple times in additional microstructure fabrication processes.

In one or more embodiments, the thin-film photomask fabrication step and the microstructure photolithography can be accomplished sequentially in a single multi-coating-head production line.

In one or more alternative embodiments, the laminated structure 110 is formed by applying the photo-sensitive material 102 on the substrate 101, and then laminating the photomask film 100 on the photo-sensitive material 102. The photo-sensitive material 102 can be applied on the substrate 101 using rod, bar, blade, slot-die, and various other coating methods to allow wider thickness range control.

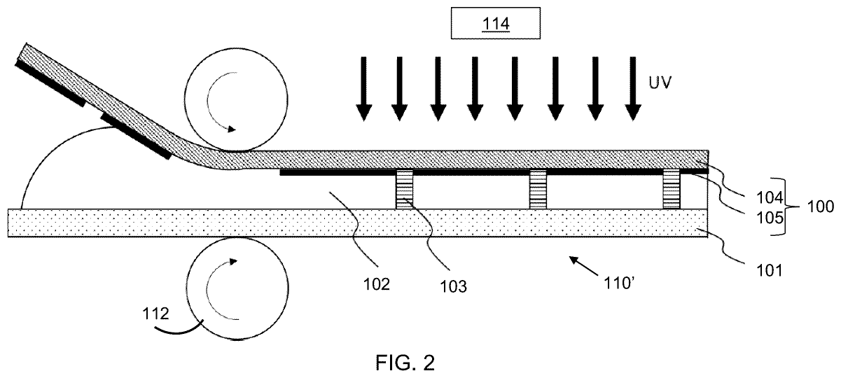

In one or more alternative embodiments, as shown in FIG. 2, the photo-sensitive material 102, the substrate 101, and the photomask film 100 form a laminated structure 110′, in which the photomask film 100 is inverted, i.e., the light blocking layer 105 of the photomask film 100 faces and is in contact with the photo-sensitive material 102. Use of such a laminated structure 110′ can reduce light scattering and enable formation of higher-resolution microstructures 103, e.g., microstructures having features smaller than 20 μm.

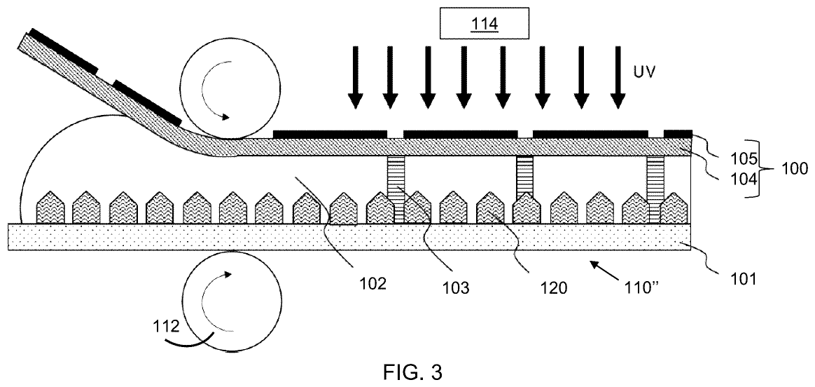

The continuous photolithography microstructure fabrication process may be adapted to fabricate multiple layers of microstructures of the same or different materials. As illustrated in FIG. 3, a substrate 101 already having a set of microstructures 120 thereon can be used to form a laminated structure 110″ with the photo-sensitive material 102 and the photomask film 100. A different set of microstructures 103 can then be patterned on the substrate 101 using the photolithography processes discussed above. In this way, multiple sets of microstructures 103, 120 comprising the same or different materials can be formed on the substrate 101.

The initial microstructures 120 on the substrate 101 can be fabricated using the same continuous photolithography process discussed above or can be fabricated using other processes including, e.g., embossing through a shim. The microstructures 103 and 120 can serve the same or different functions in the device in which they are incorporated.

In one or more embodiments, the thin-film photomask 100 can include grey scale features to vary the exposure intensity level of the UV light source 114 to make 3D microstructures 103 with controllable height variances.

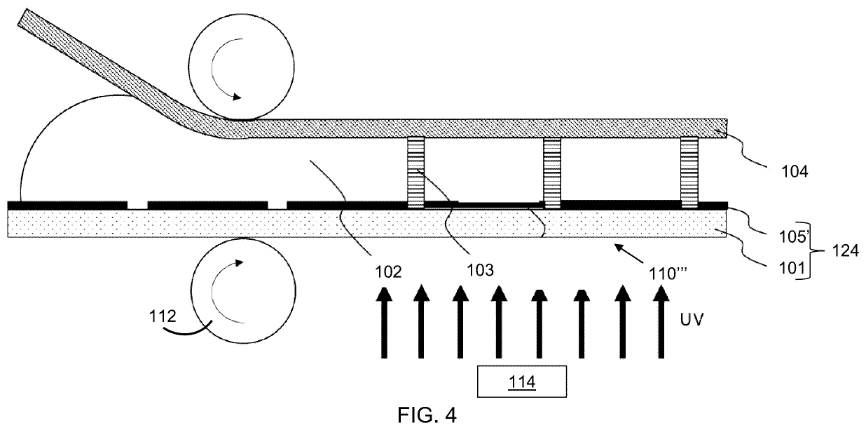

In one or more further alternate embodiments, a laminated structure 110″′ is formed in which the thin-film photomask 124 forms a bottom substrate underneath the photo-sensitive material 102 as shown in FIG. 4. The thin-film photomask 124 is intended to form a part of the final structure and is not sacrificial. The printed light-blocking layer 105 of the thin-film photomask 124 is provided on the substrate 101. The release liner 104 is removed prior to development of the photo-sensitive material 102 to form the microstructures 103. The printed light-blocking layer 105′ is transparent for visible light for use, but blocking for the g-line (436 nm) and h-line (405 nm) transmission for photo patterning. As part of the final structure, the light-blocking layer 105′ has the additional benefit during use of blocking certain types of harmful light.

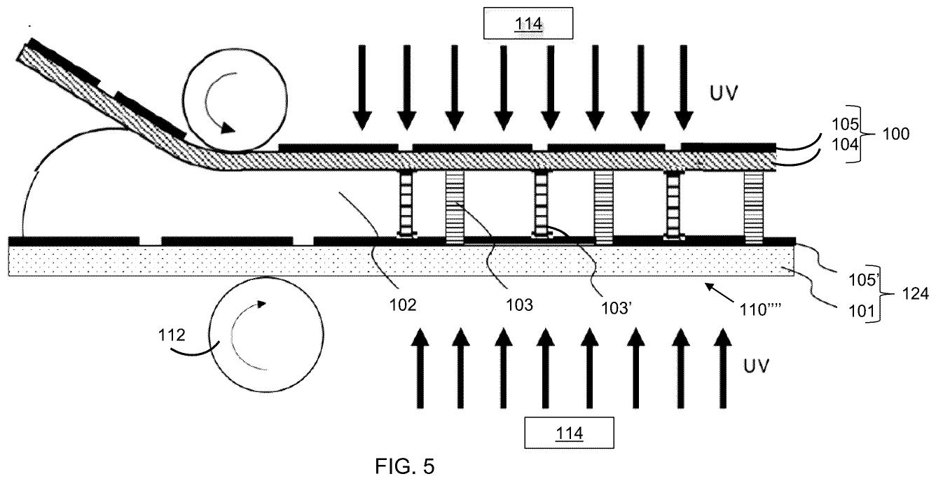

In one or more further embodiments, as shown in FIG. 5, a laminated structure 110″″ is formed comprising a first thin-film photomask 100, a second thin-film photomask 124, and photo-sensitive material 102 therebetween. The second thin-film photomask 124 comprises a printed light-blocking layer 105′ with grey scale features like the printed light-blocking layer 105′ of FIG. 4. The first thin-film photomask 100 includes a light-blocking features like the printed light-blocking layer 105 of FIG. 2. The photomasks 100, 124 form patterns of microstructures 103′, 103. Either one of the photomasks 100, 124 could remain as part of the final structure, while the other photomask is removed after the photo patterning step.

### EXAMPLES

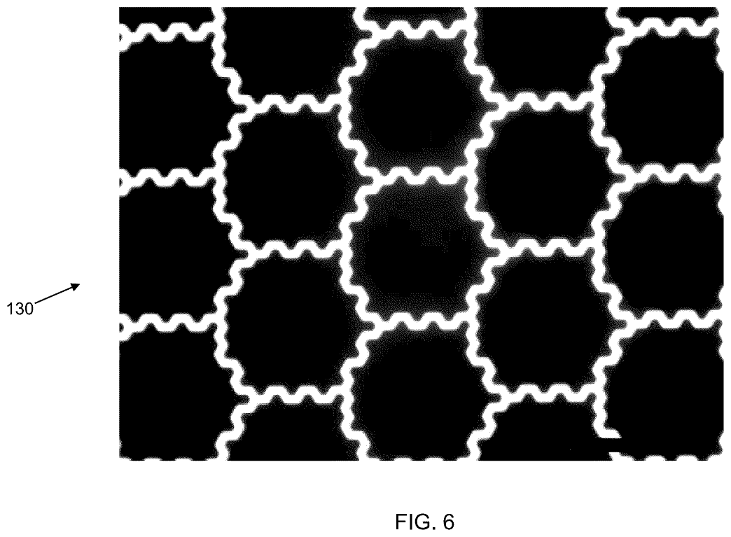

A pattern of microstructures was formed using the following process. A small drop of a blue UV resin called 127-24PB from Creative Materials was cast on an ITO-coated PET sheet. A 5×5 cm photomask 130 with an emulsion photolithographic pattern shown in FIG. 6 was hand laminated on top of the resin on the PET-ITO sheet.

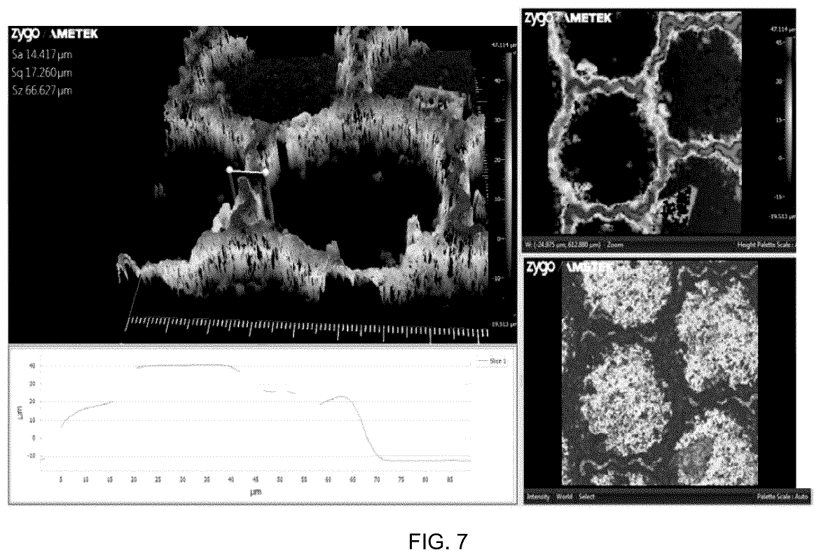

The photomask 130 was then used to pattern the UV polymer into microcell walls by curing the lamination in a DECO Delolux 03S curing lamp for 30 seconds. The photomask 130 was then peeled off and the uncured resin, cured resin, and PET-ITO sheet was soaked in Isopropyl Alcohol (IPA) for 1 minute, and the uncured resin was wiped away using a cloth. FIG. 7 shows the measured topography of the microstructure walls formed using this process.

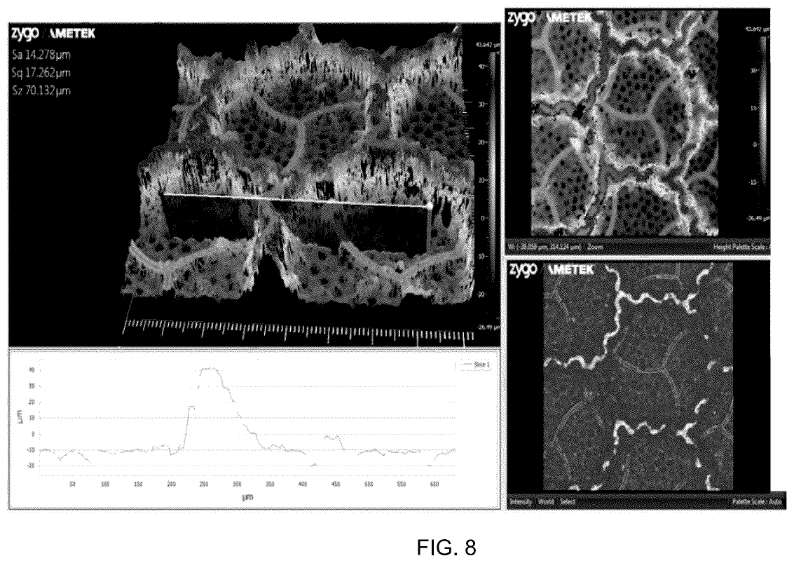

The procedure described above was then repeated, but with a PET-ITO sheet having an existing microstructure thereon similar to process described in FIG. 3. FIG. 8 shows the measured topography of the microstructure walls formed using this process.

It will be apparent to those skilled in the art that numerous changes and modifications can be made in the specific embodiments of the present invention described above without departing from the scope of the invention. Accordingly, the whole of the foregoing description is to be construed in an illustrative and not in a limitative sense.

1. A roll-to-roll seamless microstructure fabrication method comprising the steps of:
(a) continuously forming a laminated structure comprising a photomask film superimposed on a substrate with a layer of photo-sensitive material therebetween, said photomask film including a pattern of light-transmissive regions and light-blocking regions;
(b) illuminating the photomask film of laminated structure formed in step (a) with light from a light source to expose portions of the photo-sensitive material covered by the light-transmissive regions to the light, while leaving the remaining portions of the photo-sensitive material covered by the light-blocking regions unexposed to the light;
(c) delaminating the photomask film from the photo-sensitive material selectively illuminated in step (b); and
(d) selectively removing the portions of the photo-sensitive material exposed to the light or the portions of the photo-sensitive material unexposed to the light to form a layer of microstructures on the substrate.

2. The method of claim 1, wherein step (d) comprises selectively removing the portions of the photo-sensitive material exposed to the light to form a layer of microstructures on the substrate.

3. The method of claim 1, wherein step (d) comprises selectively removing the portions of the photo-sensitive material unexposed to the light to form a layer of microstructures on the substrate.

4. The method of claim 1, wherein in step (b) the portions of the photo-sensitive material exposed to the light are cured by the light, while the remaining portions of the photo-sensitive material remain uncured; and wherein in step (d) the uncured portions of the photo-sensitive material are removed to form the layer of microstructures on the substrate from the cured portions of the photo-sensitive material.

5. The method of claim 1, wherein the light comprises ultra-violet light.

6. The method of claim 1, wherein the photo-sensitive material comprises a negative type ultra-violet sensitive material.

7. The method of claim 1, wherein the microstructures comprise cross-linked ultra-violet light cured structures.

8. The method of claim 1, wherein step (a) comprises advancing the photomask film, the substrate, and the layer of photo-sensitive material between a pair of pinch rollers to form the laminated structure.

9. The method of claim 1, further comprising reusing the photomask film delaminated in step (c) in a subsequent microstructure fabrication process.

10. The method of claim 1, wherein step (b) is performed while the laminated structure is in transit.

11. The method of claim 1, wherein the layer of photo-sensitive material is coated on the substrate prior to step (a).

12. The method of claim 1, wherein the substrate laminated in step (a) includes a preexisting set of microstructures formed thereon.

13. The method of claim 1, further comprising withdrawing the photomask film and the substrate from rolls prior to step (a).

14. The method of claim 13, wherein the width of each roll is greater than 1 m.

15. The method of claim 1, wherein the microstructures comprise features having an X/Y dimension resolution of 20 μm to 2000 μm and a Z dimension resolution of 1 μm to 500 μm.

16. The method of claim 1, wherein the substrate having the layer of microstructures formed thereon has a width greater than one meter and a length greater than 1 m.

17. The method of claim 1, wherein step (d) comprises introducing the photo-sensitive material and substrate in a solvent bath for dissolving the portions of the photo-sensitive material to be removed.

18. The method of claim 1, wherein the microstructure fabrication method produces a seamless roll of the substrate with the layer of microstructures thereon.

19. The method of claim 1, wherein the photomask film comprises a photomask pattern printed on a release liner, wherein the photomask pattern faces and is adjacent to the photo-sensitive material, and wherein the release liner faces and is adjacent to the photo-sensitive material.

20. The method of claim 1, wherein the layer of microstructures on the substrate is used in constructing an electrophoretic device.

21. The method of claim 1, wherein the photomask film includes grey scale features to alter the intensity of the light incident on the photo-sensitive material to vary the heights of the microstructures.

22. A layer of microstructures on a substrate produced by the method of claim 1.
